(19) United States
(12) Patent Application Publication
(10) Pub. No.: US 2011/0154929 A1
(43) Pub. Date: Jun. 30, 2011

(54) WAFER TRANSFER APPARATUS AND SHIELDING MECHANISM

(75) Inventors: Lay Huat Ang, Singapore (SG); Boon Chung Alvin Lim, Singapore (SG); Lei Zhang, Singapore (SG); Feng Liu, Singapore (SG)

(73) Assignee: UNITED MICROELECTRONICS CORP., Hsinchu (TW)

(21) Appl. No.: 12/649,752

(22) Filed: Dec. 30, 2009

(51) Int. Cl. H01L 21/67; B25J 11/00; H01L 21/677

(52) U.S. Cl. 74/469

(57) ABSTRACT

A wafer transfer apparatus includes a main body, a wafer carrier, a linkage and a shielding mechanism. The linkage includes a first connecting rod and a pair of second connecting rods. The wafer carrier connects with a first side of the first connecting rod. A first terminal of each second connecting rod pivotedly connects with two ends of the first connecting rod. The shielding mechanism on the first connecting rod includes a shielding part and two fixing parts. The shielding part is configured at the first side of the first connecting rod for shielding a pivot joint between the first connecting rod and each second connecting rod. The fixing parts connect with both sides of the shielding part, and are respectively configured at a second and a third sides of the first connecting rod so as to fix the shielding part at the first side of the first connecting rod.

### BACKGROUND OF THE INVENTION

1. Field of Invention

The present invention relates to a semiconductor process apparatus, and more particularly to a wafer transfer apparatus having a shielding mechanism.

2. Description of Related Art

Because of the continuous high integration density of semiconductor devices of integrated circuits, manufacturing process accuracy becomes more and more important. Once minor errors occur during processes, the whole manufacturing process may fail. As a result, wafers are damaged and scraped, and costs thus increase.

For a general semiconductor process, a semiconductor equipment is composed of several neighboring process chambers. By a wafer transfer system, wafers are transferred among different process chambers. During the wafer transfer among the process chambers, a robot blade takes wafers from a cassette and transfers the wafers to the process chambers for processing. Then, the wafers are taken out from the process chambers and transferred to the process chamber for the next process step. After the process is complete, the wafers are transferred to the cassette to finish a series of process steps.

The motions of a robot blade are complicated which include rotating, extending, retracting and so on. Generally, the robot blade utilizes the combinations of transmission elements such as rod parts and bearings to implement the aforementioned motions. However, the frequency for using the robot blade to transfer wafers is high. Hence, the material of transmission elements easily ages, has been worn out and even deformed so that the particles of the transmission elements are generated and fall. During the process for transferring the wafer by the robot blade, the falling particles flowing along the flowing direction of the process gas leads to the streamline shape defects on the wafer or the surface scratch of the wafer or even the broken wafer circumstance. Besides, with the increasing of the time for performing the process on the process equipment, the aforementioned situations such as material aging and being worn out are getting serious. Therefore, when the process equipment operates for a period of time, it is necessary to shutdown the process equipment to repair aging or worn-out transmission elements. Thus, the time is wasted, the cost is increased, and the production yield is seriously affected.

### SUMMARY OF THE INVENTION

The invention provides a wafer transfer apparatus having a shielding mechanism and capable of preventing from particle falling.

The invention provides a wafer transfer apparatus having a main body, a wafer carrier, a linkage and a shielding mechanism. The linkage is used to connect the wafer carrier to the main body. The linkage comprises a first connecting rod and a pair of second connecting rods. The wafer carrier is connected to a first side of the first connecting rod. A first terminal of each of the second connecting rods is pivotedly connected to two ends of the first connecting rod respectively. The shielding mechanism is assembled on the first connecting rod. The shielding mechanism includes a shielding part and two fixing parts. The shielding part is configured at the first side of the first connecting rod for at least shielding a pivot joint between the first connecting rod and each of the second connecting rods. The fixing parts are connected to both sides of the shielding part respectively, and respectively configured at a second side and a third side of the first connecting rod so as to fix the shielding part at the first side of the first connecting rod.

The invention further provides a shielding mechanism for a wafer transfer apparatus. The wafer transfer apparatus at least comprises a first connecting rod and a second connecting rod pivotedly connected to the first connecting rod. The first connecting rod is connected to a wafer carrier. A periphery surface of a pivot joint between the first connecting rod and the second connecting rod has a groove facing the wafer carrier. The shielding mechanism is assembled on the first connecting rod. The shielding mechanism includes a shielding part and at least a fixing part. The shielding part and the wafer carrier are configured at a same side of the first connecting rod for at least shielding the pivot joint between the first connecting rod and the second connecting rod. The fixing part is connected to the shielding part and configured on a rod body portion of the first connecting rod for fixing the shielding part.

In one embodiment of the present invention, each of the ends of the first connecting rod has a concave and the first terminal of the second connecting rod is configured in the concave. In the concave, there can be, for example, a groove at the periphery surface of the pivot joint between the first connecting rod and the second connecting rod and the groove faces the first side of the first connecting rod.

In one embodiment of the present invention, the wafer transfer apparatus further comprises a bearing configured on the pivot joint between the first connecting rod and the second connecting rod.

In one embodiment of the present invention, the linkage further comprises a pair of third connecting rods, and a third terminal of each of the third connecting rods is pivotedly connected to a second terminal of each of the corresponding second connecting rods, and a fourth terminal of each of the third connecting rods is connected to the main body.

In one embodiment of the present invention, each of the fixing parts further comprises at least an opening. The opening can be, for example, configured on the pivot joint between the first connecting rod and each of the second connecting rods. The opening can also be, for example, configured on the rod body portion of the first connecting rod.

In one embodiment of the present invention, each of the fixing parts further comprises at least a fixing hole for fixing the fixing parts on the first connecting rod.

In one embodiment of the present invention, the first connecting rod is closely in contact with the shielding mechanism.

In one embodiment of the invention, the shielding mechanism is formed as a whole.

In one embodiment of the invention, the material of the shielding mechanism includes stainless steel.

Accordingly, the wafer transfer apparatus of the present invention has a shielding mechanism for at least shielding the pivot joint between the first connecting rod and each of the second connecting rods. Even the particles generated due to the element aging and worn out happening on the wafer transfer apparatus, the shielding mechanism staying close to the periphery of the pivot joint between the first connecting rod and the second connecting rod can wrap the particles therein so as to effectively prevent from the falling particles on the wafers or in the process chambers. Hence, the present invention can decrease the defects such as wafer scratch caused by the particles, and can further prolong the cycle time for replacing the parts so that the down time is decreased and the throughput is increased. Thus, the cost of the preventive maintenance is decreased.

Moreover, the shielding mechanism of the present invention is designed according to the profile structure of the connecting rod so that the shielding mechanism can be closely enclosing the pivot joints between the connecting rods. Therefore, the design of the shielding mechanism can be adjusted according to the current structure of the wafer transfer apparatus so that the shielding mechanism can be applied in various semiconductor process equipments.

In order to make the aforementioned and other features and advantages of the present invention more comprehensible, several embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic top view showing a wafer transfer apparatus according to one embodiment of the present invention.

FIG. 2 is a schematic perspective view showing a portion of a wafer transfer apparatus according to one embodiment of the present invention.

FIGS. 3A through 3C are schematic cross-sectional views showing a wafer transfer apparatus from different angles according to one embodiment of the present invention.

FIG. 4 is a partially enlarged schematic view showing a pivot joint between the first connecting rod and the second connecting rod shown in FIG. 2.

### DESCRIPTION OF EMBODIMENTS

The following descriptions of embodiments refer to accompanying drawings so as to demonstrate the specific embodiments by which the present invention can be implemented. In the following embodiments, wordings used to indicate directions, such as “up,” “down,” “front,” “back,” “inside,” and “outside”, merely refer to directions in the accompanying drawings. Hence, people skilled in the art should be able to embody the present invention based on the wording used to indicate directions in the following descriptions, whereas the scope of the present invention is not limited thereby.

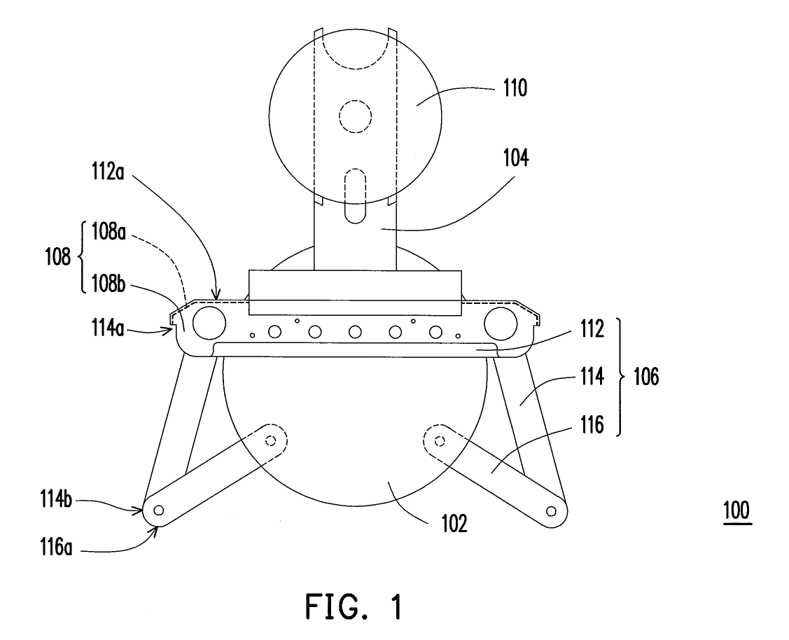

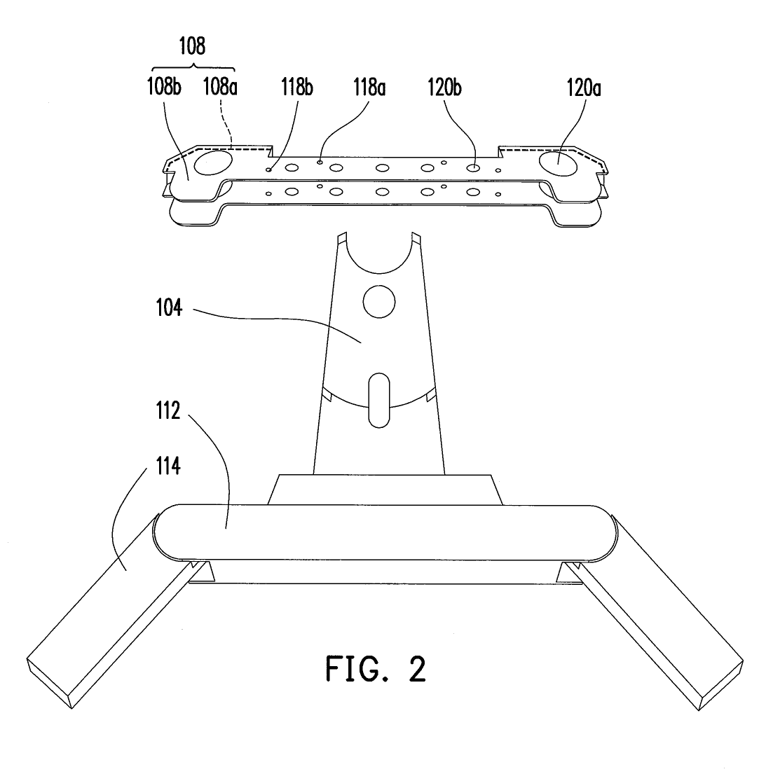

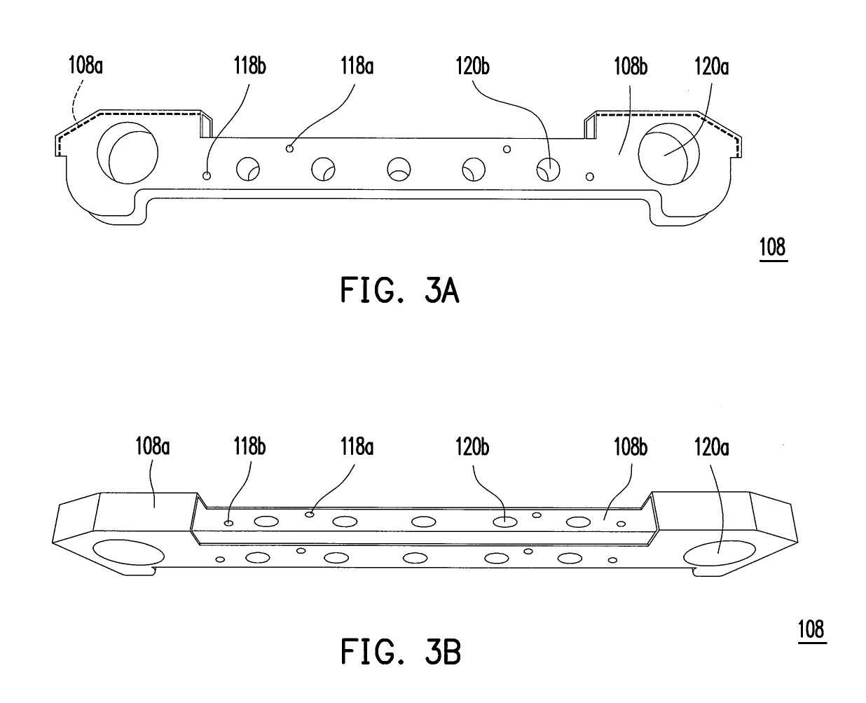

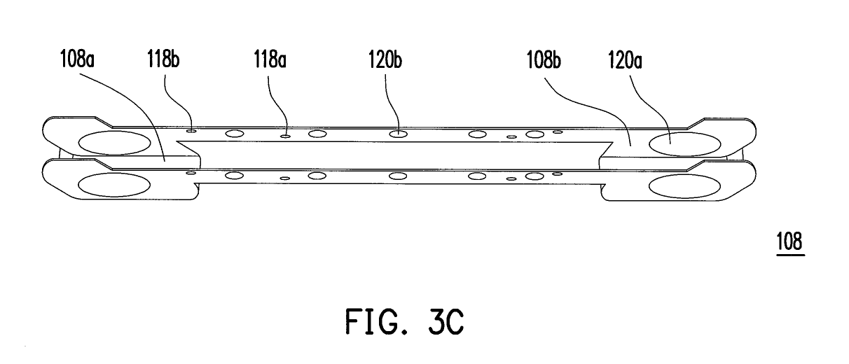

FIG. 1 is a schematic top view showing a wafer transfer apparatus according to one embodiment of the present invention. FIG. 2 is a schematic perspective view showing a portion of a wafer transfer apparatus according to one embodiment of the present invention. FIGS. 3A through 3C are schematic cross-sectional views showing a wafer transfer apparatus from different angles according to one embodiment of the present invention.

As shown in FIG. 1, the invention provides a wafer transfer apparatus 100 at least having a main body 102, a wafer carrier 104, a linkage 106 and a shielding mechanism 108. The wafer carrier 104 can be, for example, a plate carrier. Of course, the shape of the wafer carrier 104 is not specified. It can be designed based on the different requirements. The method for the wafer carrier 104 to support a wafer 110 can be, for example, electrostatic adsorption or vacuum suction. Furthermore, the linkage 106 connects the wafer carrier 104 to the main body 102 so that the wafer transfer apparatus 100 can horizontally move or rotational shift along a fix plane. The aforementioned horizontal movement or rotational shift can be individually carried out or performed together so as to transfer the wafer from the original location to other locations. For instance, the wafer can be transferred from one of the process chambers to another process chamber for performing a predetermined next process.

In one embodiment, the linkage 106 can have a frog-leg type configuration. Specifically, the linkage 106 includes a first connecting rod 112, a pair of second connecting rods 114 and a pair of third connecting rods 116. The first connecting rod 112 can be, for example, configured over the main body 102 and separated from the main body 102. The wafer carrier 104 is connected to a first side of the first connecting rod 112. The combinations of the second connecting rods 114 and the third connecting rods 116 can be symmetrically connected to two ends 112a of the first connecting rod 112. The second connecting rods 114 and the third connecting rods 116 can be, for example, configured at another side of the first connecting rod 112 in opposition to the wafer carrier 104. That is, the second connecting rods 114 and the third connecting rods 116 are configured at a side of the first connecting rod 112 opposite to the first side of the first connecting rod 112.

Accordingly, one end 112a of the first connecting rod 112 is pivotedly connected to one terminal 114a of one of the second connecting rods 114, and the other terminal 114b of the second connecting rod 114 is pivotedly connected to one terminal 116a of the corresponding third connecting rod 116. Moreover, the other terminal of the third connecting rods 116 is connected to the motor (not shown) inside the main body 102 so that the motor can control the movement of the third connecting rods 116. More particularly, when the movements of the third connecting rods 116 are controlled by the main body 102, the second connecting rods 114 move with the movements of the third connecting rods 116 respectively. Consequently, the wafer carrier 104 is driven to extend or retract through the first connecting rod 112. Hence, the wafer 110 can be transfer to the process chambers on demands.

As shown in FIG. 2, the shielding mechanism 108 is assembled on the first connecting rod 112. The shielding mechanism 108 comprises a shielding part 108a and two fixing parts 108b. The shielding mechanism 108 can be, for example, formed as a whole, and the material of the shielding mechanism 108 can be, for example stainless steel. In one embodiment, the shielding mechanism 108 can be designed according to profile of the first connecting rod 112 so that the shielding mechanism 108 can be closely in contact with the first connecting rod 112 along the profile structure of the first connecting rod 112.

Notably, people skilled in the art should be able to embody the present invention based on the following embodiments which are detailed by using the shielding mechanism 108 shown in FIG. 2, FIGS. 3A through 3C as an example, whereas the scope of the present invention is not limited thereby. Namely, the numbers, the structures and the arrangements of the shielding parts 108a and the fixing parts 108b are not specifically restricted in the present invention.

More clearly, as shown in FIG. 2 together with FIGS. 3A through 3C, the shielding part 108a is configured on the first side of the first connecting rod 112. That is, the shielding part 108a and the wafer carrier 104 are configured at the same side of the first connecting rod 112. The shielding part 108a can be used to at least shield the pivot joints between the first connecting rod 112 and each of the second connecting rods 114. In one embodiment, since the two ends 112a of the first connecting rod 112 are pivotedly connected to the second connecting rods 114 respectively, the shielding mechanism 108 can also have two shielding parts 108a to shield the pivot joints at the two ends 112a of the first connecting rod 112. Moreover, the two shielding parts 108a can be, for example, separated from each other so that there is a hole between the two shielding parts 108a. The distance between the two shielding parts can be, for example, designed to be corresponding to the wafer carrier 104 so that the wafer carrier 104 can penetrate through the hole between the two shielding parts 108a. That is, when the shielding mechanism 108 is assembled on the first connecting rod 112, the shielding mechanism 108 sheathes the first connecting rod 112 from the side where the wafer carrier 104 is located. Meanwhile, the wafer carrier 104 connected to the first connecting rod 112 penetrates through the hole between the two shielding parts 108a.

The fixing parts 108b are connected to the shielding part 108a, and the two fixing parts 108b are configured at a second side of the first connecting rod 112 and a third side of the first connecting rod 112 respectively. In other words, the two fixing parts 108b can be, for example, configured over and under the first connecting rod 112 so that the shielding part 108a connected between the two fixing parts 108b can be stably fixed at the side as same as where the wafer carrier 104 is located. Each of the fixing parts 108b further comprises at least one fixing hole 118a for fixing the fixing part 108b on the first connecting rod 112. In one embodiment, as shown in FIG. 2, each of the fixing parts 108b comprises two fixing holes 118a, for example, symmetrically configured, with respect to the intermediate axis between the fixing parts 108b, to be close to the wafer carrier 104. In another embodiment, the fixing holes 118b of each of the fixing parts 108b can be also symmetrically configured to be close to the pivot joint between the first connecting rod 112 and the second connecting rod 114. Of course, in other embodiments, the locations and the numbers of the fixing holes can be varied on demands, and the fixing parts 108b can be fixed on the first connecting rod 112 by other methods as long as the shielding mechanism 108 can be closely in contact with the first connecting rod 112. Also, the numbers and the locations of the fixing holes and the way to fix the fixing parts on the first connecting rod are not limited to in the present invention.

In one embodiment, the fixing parts 108b further comprises at least an opening 120a and/or at least an opening 120b to decrease the whole weight of the shielding mechanism 108. The openings 120a can be, for example, configured over the pivot joints between the first connecting rod 112 and each of the second connecting rods 114 respectively. The openings 120b can be also configured over or under the rod body portion of the first connecting rod 112. In the aforementioned embodiment, each of the fixing parts 108b configured with two round shape openings 120a and five round shape openings 120b is used as an example for the explanation. However, the invention is not limited by the aforementioned opening arrangements. The number and the shapes of openings configured on the fixing parts 108b can be varied as long as the weight of the shielding mechanism is decreased without jeopardizing the functions of the shielding mechanism 108. Also, the number and the shapes of openings configured on the fixing parts 108b can be adjusted by people skilled in the art according to the practical requirements.

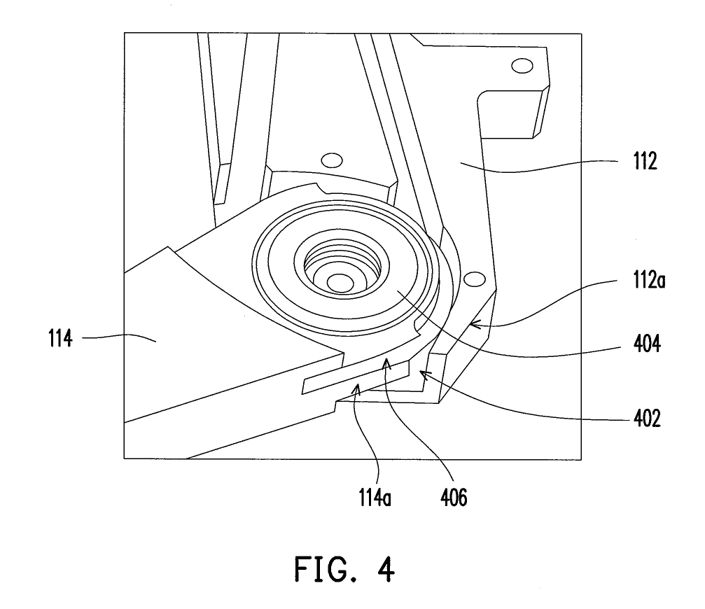

FIG. 4 is a partially enlarged schematic view showing a pivot joint between the first connecting rod and the second connecting rod shown in FIG. 2. The upper cover of the pivot joint between the first connecting rod and the second connecting rod omitted for the convenience of descriptions.

As shown in FIG. 4, the end 112a of the first connecting rod 112 can, for example, has a concave 402, and one terminal 114a of the second connecting rod 114 is configured in the concave 402. Moreover, a bearing 404 is configured on the pivot joint between the first connecting rod 112 and the second connecting rod 114 so that the terminal 114a of the second connecting rod 114 in the concave 402 is pivotedly connected to the end 112a of the first connecting rod 112. The bearing 404 can be, for example, a ball bearing. To smoothly rotate the second connecting rod 114, there is a groove 406 at the periphery surface pivot joint between the first connecting rod 112 and the second connecting rod 114 in the concave 402. The structure of the concave 402 near the second connecting rod 114 is a sidewall-less open structure. Therefore, even the bearing 404 is covered by an upper cover, the groove 406 at the periphery surface of each of the pivot joints is still exposed.

When the shielding mechanism 108 is assembled on the first connecting rod 112, the shielding part 108a at least shields the pivot joints between the first connecting rod 112 and each of the second connecting rods 114. That is, the groove 406 at the periphery surface of each of the pivot joints between the first connecting rod and each of the second connecting rod is covered by the shielding part 108a. Therefore, when the bearing 404 at each of the pivot joints between the first connecting rod 112 and each of the second connecting rods 114 ages or is worn out to generate particles, the shielding mechanism 108 closely in contact with the pivot joints between the first connecting rod 112 and each of the second connecting rods 114 can enclose the particles therein even though the particles pass through the grooves 406 at the periphery surfaces of the pivot joints. Therefore, the wafer or the process chamber can be prevented from the falling particles and the wafer scratch problem due to the particles can be overcome. Moreover, since the use of the shielding mechanism 108 can decrease the amount of the particles due to the bearing aging, the cycle time for replacing the bearing 404 is prolonged. Thus, the down time is decreased and the throughput is increased. Further, the cost of the preventive maintenance is decreased.

Accordingly, the wafer transfer apparatus of the present invention has a shielding mechanism for at least shielding the pivot joints between the first connecting rod and each of the second connecting rods. Even though the bearing of each of the pivot joints between the first connecting rod and each of the second connecting rods ages or has been worn out to generate particles, the shielding mechanism can enclose the particles therein to effectively prevent the process chamber and the wafer from the falling particles. The wafer transfer apparatus of the present invention utilizes the shielding mechanism to decrease the defects such as wafer scratch caused by the particles, and to further prolong the cycle time for replacing the parts of the bearing so that the down time is decreased and the throughput is increased.

Moreover, the wafer transfer apparatus of the present invention utilizes the shielding mechanism, which is conformal to the profile design of the connecting rod, and the connecting rod is sheathed in the shielding mechanism so that the shielding mechanism is closely in contact with the pivot joint between the connecting rods. Hence, the shielding mechanism can be widely applied onto the wafer transfer apparatuses in different process equipments. Therefore, the shielding mechanism of the present invention having simple design can integrated with the current semiconductor process equipments, and the cost is greatly decreased.

Although the invention has been described with reference to the embodiments thereof, it will be apparent to one of the ordinary skills in the art that modifications to the described embodiments may be made without departing from the spirit of the invention. Accordingly, the scope of the invention will be defined by the attached claims not by the above detailed description.

What is claimed is:

1. A wafer transfer apparatus, comprising:
a main body;
a wafer carrier;
a linkage for connecting the wafer carrier to the main body, wherein the linkage includes:
a first connecting rod for connecting the wafer carrier to a first side of the first connecting rod; and
a pair of second connecting rods, wherein a first terminal of each of the second connecting rods is pivotedly connected to two ends of the first connecting rod respectively; and
a shielding mechanism assembled on the first connecting rod, wherein the shielding mechanism includes:
a shielding part configured at the first side of the first connecting rod for at least shielding pivot joints between the first connecting rod and each of the second connecting rods; and
two fixing parts connected to both sides of the shielding part respectively, and respectively configured at a second side and a third side of the first connecting rod so as to fix the shielding part at the first side of the first connecting rod.

2. The wafer transfer apparatus of claim 1, wherein each of the two ends of the first connecting rod has a concave, and the first terminals of the second connecting rods are configured in the concaves respectively.

3. The wafer transfer apparatus of claim 2, wherein there is a groove at a periphery surface of each of the pivot joints between the first connecting rod and each of the second connecting rods in the concave, and the grooves face the first side of the first connecting rod.

4. The wafer transfer apparatus of claim 1 further comprising a bearing configured on the pivot joint between the first connecting rod and each of the second connecting rods.

5. The wafer transfer apparatus of claim 1, wherein the linkage further comprises a pair of third connecting rods, and a third terminal of each of the third connecting rods is pivotedly connected to a second terminal of each of the corresponding second connecting rods, and a fourth terminal of each of the third connecting rods is connected to the main body.

6. The wafer transfer apparatus of claim 1, wherein each of the two fixing parts further comprises at least an opening.

7. The wafer transfer apparatus of claim 6, wherein the openings are correspondingly configured on the pivot joint between the first connecting rod and each of the second connecting rods.

8. The wafer transfer apparatus of claim 6, wherein the openings are correspondingly configured on a rod body portion of the first connecting rod.

9. The wafer transfer apparatus of claim 1, wherein each of the two fixing parts further comprises at least a fixing hole for fixing the two fixing parts on the first connecting rod.

10. The wafer transfer apparatus of claim 1, wherein the first connecting rod is closely in contact with the shielding mechanism.

11. The wafer transfer apparatus of claim 1, wherein the shielding mechanism is formed as a whole.

12. The wafer transfer apparatus of claim 1, wherein the material of the shielding mechanism includes stainless steel.

13. A shielding mechanism for a wafer transfer apparatus, wherein the wafer transfer apparatus at least includes a first connecting rod and a second connecting rod pivotedly connected to the first connecting rod, and the first connecting rod is connected to a wafer carrier, and a periphery surface of a pivot joint between the first connecting rod and the second connecting rod has a groove, and the groove faces the wafer carrier, and the shielding mechanism is assembled on the first connecting rod, the shielding mechanism comprising:
a shielding part, wherein the shielding part and the wafer carrier are configured at a same side of the first connecting rod for at least shielding the pivot joint between the first connecting rod and the second connecting rod; and
at least a fixing part connected to the shielding part and configured on a rod body portion of the first connecting rod for fixing the shielding part.

14. The shielding mechanism of claim 13 further comprising a bearing configured on the pivot joint between the first connecting rod and the second connecting rod.

15. The wafer transfer apparatus of claim 13, wherein each of the two fixing parts further comprises at least an opening.

16. The shielding mechanism of claim 15, wherein the openings are correspondingly configured on the pivot joint between the first connecting rod and the second connecting rod.

17. The shielding mechanism of claim 15, wherein the openings are correspondingly configured on the rod body portion of the first connecting rod.

18. The shielding mechanism of claim 13, wherein each of the fixing parts further comprises at least a fixing hole for fixing the fixing parts on the first connecting rod.

19. The shielding mechanism of claim 13, wherein the first connecting rod is closely in contact with the shielding mechanism.

20. The shielding mechanism of claim 13, wherein the shielding mechanism is formed as a whole.

21. The shielding mechanism of claim 13, wherein the material of the shielding mechanism includes stainless steel.
